(19) United States
(12) Patent Application Publication
(10) Pub. No.: US 2015/0096882 A1
(43) Pub. Date: Apr. 9, 2015

(54) PLASMA PROCESSING APPARATUS AND PLASMA PROCESSING METHOD

(71) Applicant: Tokyo Electron Limited, Tokyo (JP)

(72) Inventors: Naoki Matsumoto, Kurokawa-gun (JP); Koji Koyama, Kurokawa-gun (JP); Toshihisa Ozu, Hwaseong-shi (KR); Shota Yoshimura, Kurokawa-gun (JP)

(21) Appl. No.: 14/402,371

(22) PCT Filed: Jun. 14, 2013
(86) PCT No.: PCT/JP2013/066507

§ 371 Date: Nov. 20, 2014

(30) Foreign Application Priority Data
Jun. 20, 2012 (JP) 2012-139015

(51) Int. Cl. H01J 37/32; C23F 4/00

(52) U.S. Cl. CPC H01J 37/32449; C23F 4/00
USPC 204/192.32; 204/298.33

(57) ABSTRACT

A plasma processing apparatus 1 includes a central inlet unit that introduces a processing gas containing at least one of an Ar gas, a He gas and an etching gas toward a central portion of a wafer W; a peripheral inlet unit 61 that introduces the processing gas toward a periphery portion thereof; a flow rate adjusting unit that adjusts a flow rate of the processing gas introduced toward the central portion thereof from the central inlet unit 55 and a flow rate of the processing gas introduced toward the periphery portion thereof from the peripheral inlet unit 61; and a controller 49 that controls the flow rates of the processing gas adjusted by the flow rate adjusting unit such that a partial pressure ratio of the He gas to the Ar gas contained in the processing gas is equal to or higher than a preset value.

### TECHNICAL FIELD

The various embodiments described herein pertain generally to a plasma processing apparatus and a plasma processing method.

### BACKGROUND

In a semiconductor manufacturing process, a plasma process is widely performed for the thin film deposition, the etching, and so forth. To manufacture a highly functional high-performance semiconductor device, it is required to perform a uniform plasma process on a processing target surface of a substrate.

Widely used in a recent plasma process is a plasma processing apparatus configured to perform a process on a substrate accommodated in a processing vessel by exciting a processing gas introduced in the processing vessel into plasma. In such a plasma processing apparatus, a processing gas is introduced into a processing vessel by using a dual-line system. This plasma processing apparatus may include, for example, a central inlet unit configured to introduce a processing gas toward a central portion of a substrate and a peripheral inlet unit configured to introduce the processing gas toward a periphery portion of the substrate. The plasma processing apparatus introduces the processing gas into the processing vessel from the central inlet unit, and then, the peripheral inlet unit and processes the substrate by exciting the introduced processing gases into plasma. For example, a gaseous mixture of an inert gas such as an Ar gas and an etching gas such as HBr is used as the processing gas introduced into the processing vessel from the central inlet unit and the periphery inlet unit.

In this plasma processing apparatus, in order to perform a uniform plasma process on a processing target surface of the substrate, it is considered to introduce a processing gas containing another inert gas, which is more difficult to excite into plasma than the Ar gas, into the processing vessel. For example, it is described in Patent Document 1 that a He gas, which requires higher excitation energy than the Ar gas and is more difficult to excite into plasma is used as an inert gas instead of the Ar gas, and a processing gas containing the He gas and a HBr gas as an etching gas is introduced into the processing vessel.

### REFERENCES

Patent Document 1: Japanese Patent Laid-open Publication No. H05-243188

### DISCLOSURE OF THE INVENTION

### Problems to be Solved by the Invention

However, in this prior art of introducing a processing gas containing a He gas instead of an Ar gas, an electron temperature at a central portion of a substrate may become lower than an electron temperature at a periphery portion of the substrate due to the He gas which is not excited into plasma. Thus, there may be generated a discrepancy between an etching rate at the central portion of the substrate and an etching rate at the periphery portion of the substrate. As a result, in the prior art, uniformity of a processing target surface of the substrate may be deteriorated.

### Means for Solving the Problems

In one example embodiment, a plasma processing apparatus that performs a process on a substrate accommodated in a processing vessel by exciting a processing gas introduced in the processing vessel into plasma includes a central inlet unit configured to introduce a processing gas containing at least one of an Ar gas, a He gas and an etching gas toward a central portion of the substrate; a peripheral inlet unit configured to introduce the processing gas toward a periphery portion of the substrate; a flow rate adjusting unit configured to adjust a flow rate of the processing gas introduced toward the central portion of the substrate from the central inlet unit, and, also, configured to adjust a flow rate of the processing gas introduced toward the periphery portion of the substrate from the peripheral inlet unit; and a controller configured to control the flow rates of the processing gas adjusted by the flow rate adjusting unit such that a partial pressure ratio of the He gas to the Ar gas contained in the processing gas is equal to or higher than a preset value.

### Effect of the Invention

In accordance with the various example embodiments, a plasma processing method and a plasma processing apparatus capable of maintaining uniformity of a processing target surface of a substrate are provided.

### BRIEF DESCRIPTION OF THE DRAWINGS

FIG. 1 is a longitudinal cross sectional view of a plasma processing apparatus in accordance with an example embodiment.

FIG. 2 is a cross sectional view taken along a line X-X of FIG. 1.

FIG. 3 is a diagram for describing a discrepancy in etching rates at a central portion of a wafer and a periphery portion thereof.

FIG. 4 is a flowchart for describing a processing sequence of a plasma processing method performed in the plasma processing apparatus in accordance with the example embodiment.

FIG. 5A is a diagram for describing an effect of the plasma processing method in accordance with the example embodiment.

FIG. 5B is a diagram for describing an effect of the plasma processing method in accordance with the example embodiment.

FIG. 6 is a diagram showing simulation results of investigating the effects of the plasma processing method shown in FIG. 5A and FIG. 5B.

### MODE FOR CARRYING OUT THE INVENTION

Hereinafter, example embodiments will be elaborated with reference to the accompanying drawings, which form a part hereof. In the drawings, similar symbols typically identify similar components.

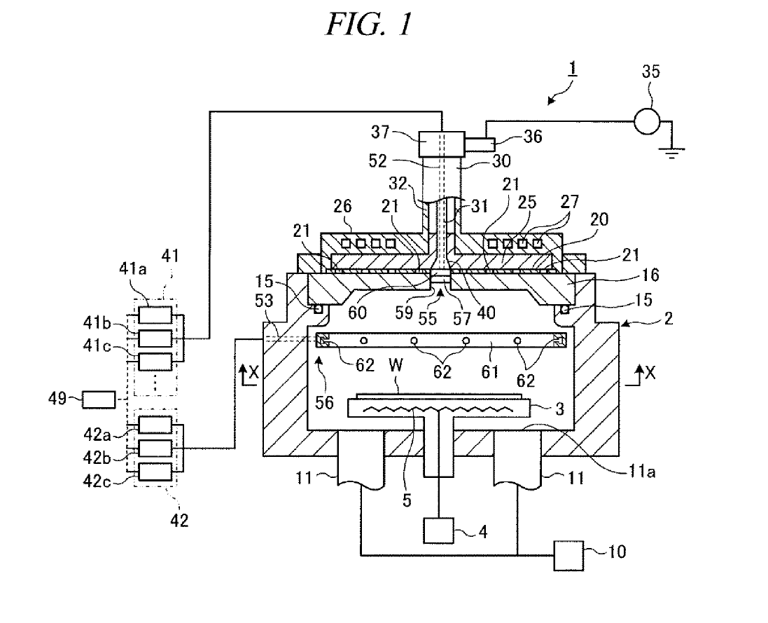

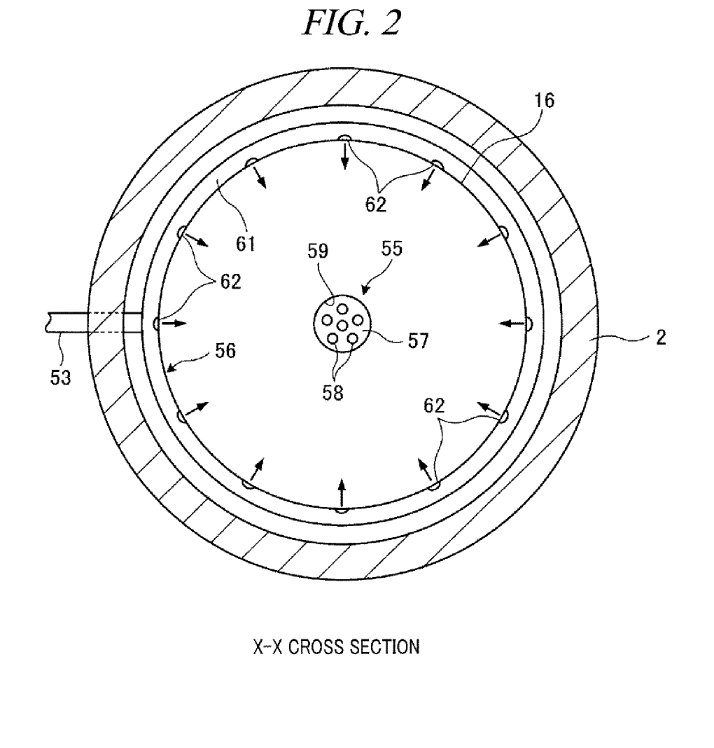

FIG. 1 is a longitudinal cross sectional view of a plasma processing apparatus in accordance with an example embodiment, and FIG. 2 is a cross sectional view taken along a line X-X of FIG. 1. As depicted in FIG. 1, a plasma processing apparatus 1 includes a cylindrical processing vessel 2. A ceiling of the processing vessel 2 is covered with a dielectric window (ceiling plate) 16 made of a dielectric material. The processing vessel 2 is made of, but not limited to, aluminum and is electrically installed. An inner wall surface of the processing vessel 2 is coated with a protective film such as alumina.

A mounting table 3 configured to mount thereon a semiconductor wafer (hereinafter, simply referred to as “wafer”) W as a substrate is provided at the center of a bottom portion of the processing vessel 2. The wafer W is held on a top surface of the mounting table 3. The mounting table 3 is made of a ceramic material such as, but not limited to, alumina or aluminum nitride. A heater 5 is embedded in the mounting table 3 and configured to heat the wafer W to a preset temperature. The heater 5 is connected to a heater power supply 4 via a wiring embedded in a supporting column.

An electrostatic chuck (not shown) configured to electrostatically attract and hold the wafer W mounted on the mounting table 3 is provided on the top surface of the mounting table 3. A high frequency bias power supply configured to apply a high frequency bias power via a matching device is connected to the electrostatic chuck.

A gas exhaust pipe 11 for exhausting a processing gas from a gas exhaust opening 11a located below a surface of the wafer W mounted on the mounting table 3 is provided at the bottom portion of the processing vessel 2. A pressure control valve and a vacuum pump 10 are connected to the gas exhaust pipe 11, and an internal pressure of the processing vessel 2 is adjusted to a preset temperature by the pressure control valve and the vacuum pump 10. The gas exhaust pipe 11, the pressure control valve and the vacuum pump 10 constitute a gas exhaust unit.

The dielectric window 16 is provided at the ceiling of the processing vessel 2 via a seal member 15 for securing airtightness. The dielectric window 16 is made of a dielectric material such as, but not limited to, quartz, alumina (Al₂O₃) or aluminum nitride (AlN) and is microwave-transmissive.

A circular plate-shaped slot antenna 20 is provided on a top surface of the dielectric window 16. The slot antenna 20 is made of a material having conductivity, e.g., copper plated or coated with Ag, Au, or the like. For example, the slot antenna 20 has a multiple number of T-shaped slots 21 which are concentrically arranged. The slot antenna 20 may also be referred to as a radial line slot antenna (hereinafter, simply referred to as “RLSA”).

A dielectric plate 25 configured to shorten a wavelength of a microwave is provided on a top surface of the slot antenna 20. The dielectric plate 25 is made of a dielectric material such as, but not limited to, quartz (SiO₂), alumina (Al₂O₃) or aluminum nitride (AlN). The dielectric plate 25 is covered with a conductive cover 26. An annular heat transfer medium path 27 is formed within the cover 26. The cover 26 and the dielectric plate 25 are adjusted to a preset temperature by a heat transfer medium flowing through the heat transfer medium path 27. As for a microwave having a wavelength of 2.45 GHz, for example, a wavelength of this microwave in the vacuum is about 12 cm, and a wavelength of this microwave in the dielectric window 16 made of alumina is about 3 cm to about 4 cm.

A coaxial waveguide 30 configured to propagate a microwave is connected to the center of the cover 26. The coaxial waveguide 30 includes an inner conductor 31 and an outer conductor 32, and the inner conductor 31 penetrates a center of the dielectric plate 25 and is connected to a center of the slot antenna 20.

A microwave generator 35 is connected to the coaxial waveguide 30 via a mode converter 37 and a rectangular waveguide 36. Instead of the microwave having a wavelength of 2.45 GHz, a microwave of 850 MHz, 915 MHz, 8.35 GHz, or the like may also be used.

The microwave generated by the microwave generator 35 is propagated through the rectangular waveguide 36, the mode converter 37, the coaxial waveguide 30 and the dielectric plate 25, which serve as a microwave introduction path. The microwave propagated to the dielectric plate 25 is supplied into the processing vessel 2 from the multiple number of slots 21 of the slot antenna 20 through the dielectric window 16. An electric field is formed under the dielectric window 16 by the microwave, so that the processing gas within the processing vessel 2 is excited into plasma.

A lower end of the inner conductor 31 connected to the slot antenna 20 is formed in the shape of a truncated conical trapezoid. Accordingly, the microwave can be propagated from the coaxial waveguide 30 to the dielectric plate 25 and the slot antenna 20 efficiently without a loss thereof.

Microwave plasma generated by the RLSA is characterized in that plasma generated in a region (plasma excitation region) directly under the dielectric window 16 having a relatively high electron temperature of several eV is diffused to have a low electron temperature of 1 eV to 2 eV in a region (plasma diffusion region) directly above the wafer W. That is, unlike plasma generated by the parallel plate type apparatus, a distribution of electron temperature of the microwave plasma explicitly has a function of a distance from the dielectric window 16. To elaborate, as a function of a distance from directly under the dielectric window 16, an electron temperature ranging from several eV to about 10 eV directly under the dielectric window 16 is lowered to about 1 eV to about 2 eV on the wafer W. Since the wafer W is processed in the plasma diffusion region where the electron temperature of the plasma is relatively lower, a big damage such as a recess may not be inflicted on the wafer W. If a processing gas is supplied into the plasma excitation region where the electron temperature of the plasma is relatively higher, the processing gas may be easily excited and dissociated. Meanwhile, if the processing gas is supplied into the plasma diffusion region where the electron temperature of the plasma is relatively lower, the degree of the plasma dissociation may be reduced, as compared to the case of supplying the processing gas to the vicinity of the plasma excitation region.

A central inlet unit 55 configured to introduce a processing gas toward a central portion of the wafer W is provided in the center of the dielectric window 16 at the ceiling of the processing vessel 2. The central inlet unit 55 is configured to introduce a processing gas containing at least one of an Ar gas, a He gas and an etching gas such as an HBr gas toward the central portion of the wafer W. In the present example embodiment, the central inlet unit 55 introduces a processing gas containing at least one of an Ar gas and a He gas toward the central portion of the wafer W. The central inlet unit 55 is connected with a processing gas supply path 52 formed in the inner conductor 31.

The central inlet unit 55 includes a cylindrical block 57 fitted into a cylindrical space 59 formed in the center of the dielectric window 16; a gas storage space 60 formed between a bottom surface of the inner conductor 31 and a top surface of the block 57 with a preset gap therebetween. The block 57 is made of a conductive material such as, but not limited to, aluminum and is electrically grounded. A multiple number of central inlet openings 58 (see FIG. 2) are formed through the block 57 in a vertical direction. When viewed from the top, each central inlet opening 58 is formed to have a circular or elongated hole shape in consideration of required conductance or the like. The block 57 made of aluminum is coated with anodically oxidized alumina (Al₂O₃), yttria (Y₂O₃), or the like.

The processing gas supplied into the gas storage space 60 from the supply path 52, which is formed through the inner conductor 31, is discharged downward toward the central portion of the wafer W from the multiple number of central inlet openings 58 of the block 57 after diffused in the gas storage space 60.

A ring-shaped peripheral inlet unit 61 configured to introduce a processing gas toward a peripheral portion of the wafer W is provided to surround a space above the wafer W within the processing vessel 2. The peripheral inlet unit 61 is configured to introduce a processing gas containing at least one of an Ar gas, a He gas and an etching gas such as an HBr gas toward the peripheral portion of the wafer W. In the present example embodiment, the peripheral inlet unit 61 introduces a processing gas containing an Ar gas and an HBr gas as an etching gas toward the peripheral portion of the wafer W. The peripheral inlet unit 61 is located between the central inlet openings 58 arranged at the ceiling and the wafer W mounted on the mounting table 3. The peripheral inlet unit 61 is formed of an annular hollow pipe, and a multiple number of peripheral inlet openings 62 are formed on the inner side thereof at a regular distance along the circumference thereof. The peripheral inlet openings 62 discharge the processing gas toward the center of the peripheral inlet unit 61. The peripheral inlet unit 61 may be made of, but not limited to, quartz. A supply path 53 made of stainless steel penetrates a sidewall of the processing vessel 2. The supply path 53 is connected to the peripheral inlet unit 61. The processing gas supplied into the inside of the peripheral inlet unit 61 from the supply path 53 is discharged toward the central portion of the peripheral inlet unit 61 from the multiple number of peripheral inlet openings 62 after diffused inside the peripheral inlet unit 61. The processing gas discharged from the multiple number of peripheral inlet openings 62 is supplied to a nearby space above the wafer W. Here, it is also possible to form the multiple number of peripheral inlet openings 62 in the inner sidewall surface of the processing vessel 2 instead of providing the ring-shaped peripheral inlet unit 61.

In the present example embodiment, the supply path 52 connected to the central inlet unit 55 is connected to a gas supply system 41, and the supply path 53 connected to the peripheral inlet unit 61 is connected to a gas supply system 42. The gas supply system 41 and the gas supply system 42 are configured to supply a processing gas for a plasma etching process or a plasma CVD process into the central inlet unit 55 and the peripheral inlet unit 61, respectively. By way of non-limiting example, when etching a silicon-based film such as Poly-Si, the gas supply system 41 and the gas supply system 42 supply a processing gas containing an Ar gas, a He gas, a HBr gas (or Cl₂ gas) as an etching gas, and an O₂ gas. As another example, when etching an oxide film such as SiO₂, the gas supply system 41 and the gas supply system 42 supply a processing gas containing an Ar gas, a He gas, a CHF-based gas, a CF-based gas and an O₂ gas. As yet another example, when etching a nitride film such as SiN, the gas supply system 41 and the gas supply system 42 supply a processing gas containing an Ar gas, a He gas, a CF-based gas, a CHF-based gas and an O₂ gas.

The gas supply system 41 and the gas supply system 42 may supply the same kind of processing gas or different kinds of processing gases. In the present example embodiment, for example, the gas supply system 41 supplies a processing gas containing at least one of an Ar gas and a He gas into the central inlet unit 55, whereas the gas supply system 42 supplies a processing gas containing an Ar gas and a HBr gas as an etching gas into the peripheral inlet unit 61. Accordingly, it is possible to suppress the etching gas from being excessively dissociated, and the block 57 can be suppressed from being corroded by the HBr gas which is corrosive.

The gas supply system 41 and the gas supply system 42 may also supply a cleaning gas such as O₂.

The gas supply system 41 is equipped with flow rate control valves 41a, 41b and 41c configured to control a flow rate of the processing gas supplied to the central inlet unit 55 from the gas supply system 41 through the supply path 52, i.e., the processing gas introduced from the central inlet unit 55 to the central portion of the wafer W. The flow rate control valve 41a is connected to an Ar gas source (not shown) and controls a flow rate of an Ar gas from the Ar gas source. The flow rate control valve 41b is connected to a He gas source (not shown) and controls a flow rate of a He gas from the He gas source. The flow rate control valve 4c is connected to an etching gas (e.g., a HBr gas) source (not shown) and controls a flow rate of an etching gas such as a HBr gas from the etching gas source.

The gas supply system 42 is equipped with flow rate control valves 42a, 42b and 42c configured to control a flow rate of the processing gas supplied to the peripheral inlet unit 61 from the gas supply system 42 through the supply path 53, i.e., the processing gas introduced from the peripheral inlet unit 61 to the peripheral portion of the wafer W. The flow rate control valve 42a is connected to an Ar gas source (not shown) and controls a flow rate of an Ar gas from the Ar gas source. The flow rate control valve 42b is connected to a He gas source (not shown) and controls a flow rate of a He gas from the He gas source. The flow rate control valve 42c is connected to an etching gas (e.g., a HBr gas) source (not shown) and controls a flow rate of an etching gas such as a HBr gas from the etching gas source.

The flow rate control valves 41a, 41b and 41c and the flow rate control valves 42a, 42b and 42c are controlled by a controller 49. The flow rate control valves 41a, 41b and 41c and the flow rate control valves 42a, 42b and 42c constitute an example flow rate adjusting unit.

The controller 49 may be implemented by, for example, a computer including a central processing unit (CPU) and a storage device such as a memory. The controller 49 may output various control signals according to programs stored in the storage device. The various control signals outputted from the controller 49 are inputted to the flow rate control valves 41a, 41b and 41c and the flow rate control valves 42a, 42b and 42c. By way of example, the flow rate control valves 41a, 41b and 41c adjust a flow rate of the processing gas introduced to the central portion of the wafer W from the central inlet unit 55 based on the control signal outputted from the controller 49. Further, by way of example, the flow rate control valves 42a, 42b and 42c adjust a flow rate of the processing gas introduced to the periphery portion of the wafer W from the peripheral inlet unit 61 based on the control signal outputted from the controller 49.

The controller 49 controls the flow rates of the processing gases adjusted by the flow rate control valves 41a to 41c and the flow rate control valves 42a to 42c, respectively, such that a partial pressure ratio of the He gas with respect to the Ar gas contained in the processing gases is equal to or larger than a preset value.

Here, the reason why the controller 49 controls the flow rates of the processing gases such that the partial pressure ratio of the He gas with respect to the Ar gas contained in the processing gases is equal to or larger than the present value will be discussed in detail. The He gas has higher excitation energy than the Ar gas, and is more difficult to excite into plasma. In the prior art, by using this property of the He gas, a processing gas containing only the He gas as an inert gas is introduced into the processing vessel 2 instead of the Ar gas. In the prior art, however, due to the He gas which has not yet been excited into plasma, an electron temperature at a central portion of the wafer W is excessively decreased as compared to an electron temperature at a periphery portion of the wafer W, so that a discrepancy in etching rates at the central portion and the periphery portion of the wafer W occurs.

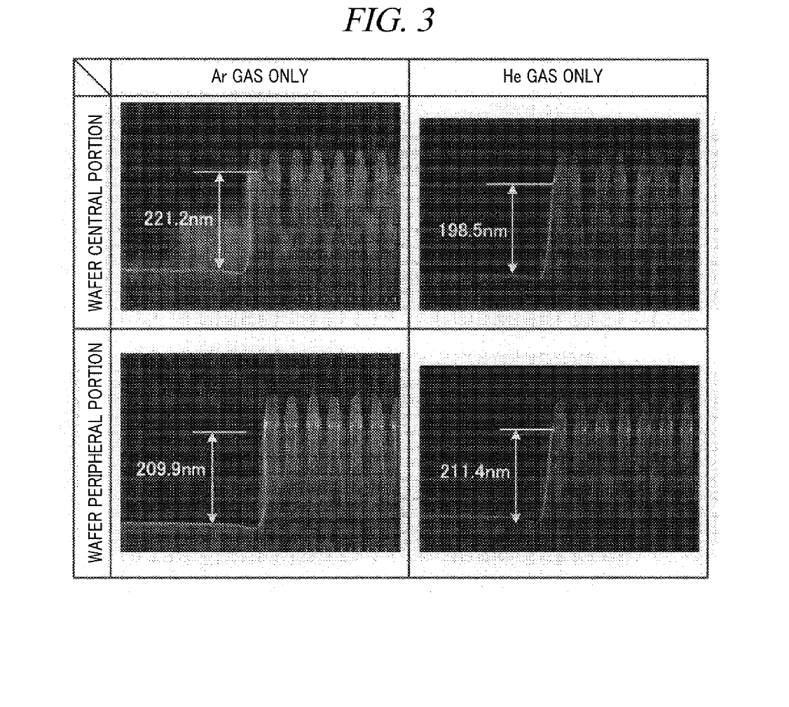

FIG. 3 is a diagram for describing a discrepancy in etching rates at a central portion of a wafer and a periphery portion thereof. FIG. 3 depicts a cross sectional image of the wafer W. Here, the etching process of removing a Poly-Si film from the wafer W for STI (Shallow Trench Isolation) is performed by introducing a processing gas containing only an Ar gas or a He gas as an inert gas into the processing vessel 2. As shown in FIG. 3, in case of introducing a processing gas containing only an Ar gas as an inert gas into the processing vessel 2, a depth ‘221.2 nm’ of a trench formed at the central portion of the wafer W is larger than a depth ‘209.9 nm’ of a trench formed at the periphery portion of the wafer W. Meanwhile, in case of introducing a processing gas containing only a He gas as an inert gas into the processing vessel 2, a depth ‘198.5 nm’ of a trench formed at the central portion of the wafer W is smaller than a depth ‘211.4 nm’ of a trench formed at the periphery portion of the wafer W. That is, in case that the processing gas containing only the He gas as the inert gas is introduced into the processing vessel 2, an etching rate at the central portion of the wafer W becomes smaller than an etching rate at the periphery portion of the wafer W.

In view of the foregoing, the present inventors have repeated researches to investigate a causal relationship between a partial pressure ratio of a He gas to an Ar gas contained in a processing gas and a discrepancy between etching rates at a central portion of a wafer W and a periphery portion thereof. As a result, the present inventors have found that the discrepancy in the etching rates at the central portion of the wafer W and the periphery portion thereof can be suppressed if the partial pressure ratio of the He gas to the Ar gas contained in the processing gas is set to be equal to or higher than a preset value. Based on this finding, the controller 49 controls a flow rate of a processing gas adjusted by the flow rate control valves 41a to 41c and the flow rate control valves 42a to 42c such that a partial pressure ratio of a He gas to an Ar gas contained in the processing gas is equal to or higher than a preset value.

Now, there will be elaborated an example process in which the controller 49 controls a flow rate of a processing gas such that a partial pressure ratio of a He gas to an Ar gas contained in the processing gas is equal to or higher than a preset value. The controller 49 stores, in a storage device, a table in which the partial pressure ratios of the He gas to the Ar gas contained in the processing gas are listed in correspondence to control values for the flow rates of the processing gases adjusted by the flow rate control valves 41a to 41c and the flow rate control valves 42a to 42c. The controller 49 receives a preset input value from an input device. Then, by referring to the table stored in the storage device, the controller 49 specifies a partial pressure ratio of the He gas to the Ar gas equal to or higher than the preset value and acquires a control value for the flow rate of the processing gas corresponding to the specified partial pressure ratio from the table. Then, base on this control value for the flow rate of the processing gas obtained from the table, the controller 49 controls the flow rates of the processing gases adjusted by the flow rate control valves 41a to 4c and the flow rate control valves 42a to 42c.

Here, desirably, the controller 49 controls the flow rates of the processing gases adjusted by the flow rate control valves 41a to 4c and the flow rate control valves 42a to 42c such that the partial pressure ratio of the He to the Ar gas contained in the processing gas is equal to or higher than 0.5 (50%).

In the present example embodiment, by controlling the flow rates of the processing gases supplied to the central portion of the wafer W and the periphery portion thereof such that the partial pressure ratio of the He gas to the Ar gas is equal to or higher than the preset value (desirably, 0.5), it is possible to obtain the uniform electron temperatures at the central portion of the wafer W and the periphery portion thereof. As a result, in accordance with the present example embodiment, a discrepancy between the etching rates at the central portion of the wafer W and the periphery portion thereof can be reduced, so that uniformity of the processing target surface of the wafer W can be maintained.

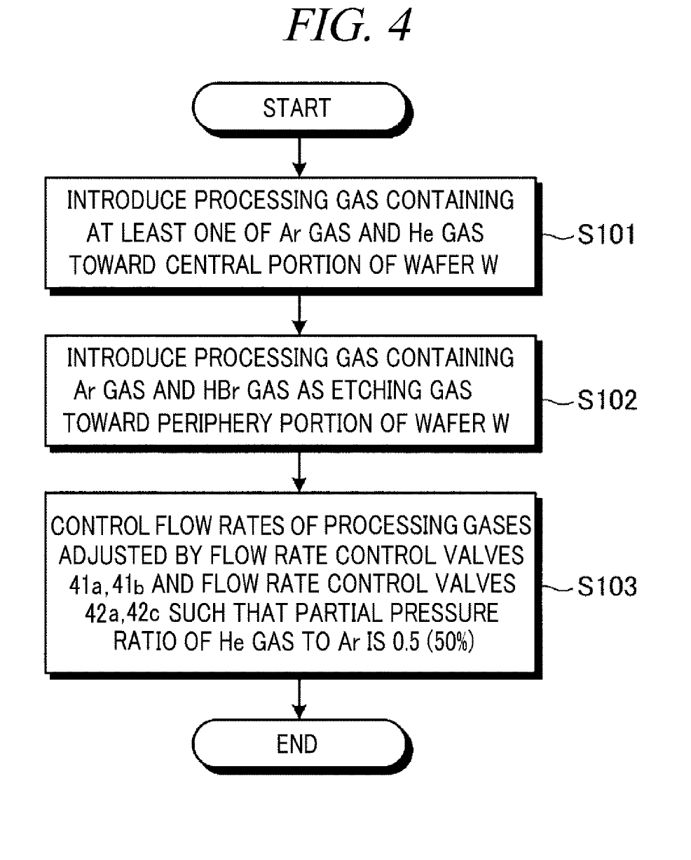

Now, a plasma processing method performed in the plasma processing apparatus 1 shown in FIG. 1 will be described. FIG. 4 is a flowchart for describing a processing sequence of the plasma processing method performed in the plasma processing apparatus in accordance with the example embodiment. The plasma processing method depicted in FIG. 4 is performed prior to performing a plasma process in which a processing gas introduced into the processing vessel 2 is excited into plasma by using, for example, a microwave generated by the microwave generator 35. As an example, processes shown in FIG. 4 are described for a case of etching a Poly-Si film on a top surface of a wafer W.

As depicted in FIG. 4, the controller 49 of the plasma processing apparatus 1 introduces a processing gas containing at least one of an Ar gas and a He gas toward a central portion of a wafer W (S101). That is, the controller 49 sends the flow rate control valves 41a and/or 41b control signals for turning the flow rate control valves 41a to 41b into an open state, so that the processing gas containing the at least one of the Ar gas and the He gas is introduced from the central inlet unit 55 toward the central portion of the wafer W.

Subsequently, the controller 49 introduces a processing gas containing an Ar gas and a HBr gas as an etching gas toward a periphery portion of the wafer W (S102). That is, the controller 49 sends the flow rate control valves 42a and 42c control signals for turning the flow rate control valves 42a and 42c into an open state, so that the processing gas containing the Ar gas and the HBr gas is introduced from the peripheral inlet unit 61 toward the periphery portion of the wafer W.

Then, the controller 49 controls the flow rates of the processing gases adjusted by the flow rate control valves 41a and 41b and the flow rate control valves 42a and 42c such that a partial pressure ratio of the He gas to the Ar gas is equal to or higher than 0.5 (50%) (S103). That is, by referring to the table stored in the storage device, the controller 49 specifies a partial pressure ratio of the He gas to the Ar gas equal to or higher than 0.5 and acquires the control values for the flow rates of the processing gases corresponding to the specified partial pressure ratio from the table. Then, base on the control values for the flow rates of the processing gases obtained from the table, the controller 49 controls the flow rates of the processing gases adjusted by the flow rate control valves 41a to 41c and the flow rate control valves 42a to 42c.

Thereafter, a plasma process of exciting the processing gas introduced in the processing vessel 2 into plasma by using the microwave generated by the microwave generator 35 is performed. If the plasma process is performed, active species such as ions are generated from the processing gas excited into plasma, and the Poly-Si film on the top surface of the wafer W is etched by the active species.

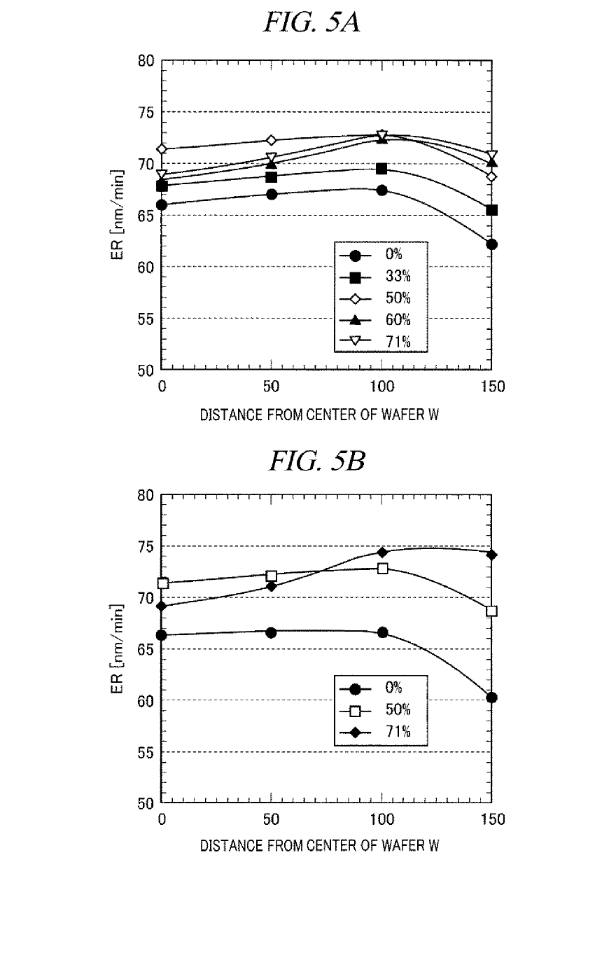

Now, an effect of the plasma processing method in accordance with the example embodiment will be described. FIG. 5A and FIG. 5B are diagrams for describing an effect of the plasma processing method in accordance with the example embodiment. FIG. 5A and FIG. 5B show an effect of the plasma processing method of the example embodiment obtained when a plasma etching process is performed on a wafer W in the plasma processing apparatus 1.

In FIG. 5A and FIG. 5B, a horizontal axis represents a distance (mm) from the center of a wafer W accommodated in the plasma processing apparatus 1. A distance ‘0’ mm from the center of the wafer W corresponds to a central portion of the wafer W, and a distance ‘150’ mm from the center of the wafer W corresponds to a periphery portion of the wafer W. Further, in FIG. 5A and FIG. 5B, a vertical axis represents an etching rate (ER) (nm/min).

FIG. 5A is a graph showing a variation of an etching rate (ER) in the range from the central portion to the periphery portion of the wafer W when a flow rate of only a He gas contained in a processing gas is adjusted such that a partial pressure ratio of the He gas to an Ar gas becomes 0%, 33%, 50%, 60% and 71%, respectively. Further, in the example shown in FIG. 5A, a flow rate of the Ar gas contained in the processing gas is fixed to 400 sccm. Meanwhile, FIG. 5B is a graph showing a variation of the etching rate (ER) in the range from the central portion to the periphery portion of the wafer W when flow rates of a He gas and an Ar gas contained in a processing gas are adjusted such that a partial pressure ratio of the He gas to the Ar gas becomes 0%, 50%, and 71%, respectively. In the example shown in FIG. 5B, a total flow rate of the processing gas containing the Ar gas, the He gas and an etching gas is fixed to 800 sccm.

As can be seen from FIG. 5A and FIG. 5B, in case of not using the plasma processing method in accordance with the example embodiment, the etching rate ER at the central portion of the wafer W is found to be higher than an etching rate at the periphery portion of the wafer W. That is, when the flow rates of the processing gases adjusted by the flow rate control valves 41a and 41b and the flow rate control valves 42a and 42c are controlled such that the partial pressure ratio of the He gas to the Ar gas is less than 50%, a discrepancy between the etching rates at the central portion of the wafer W and the periphery portion thereof is increased.

In contrast, in case of using the plasma processing method in accordance with the example embodiment, the etching rate in the entire range from the central portion to the periphery portion of the wafer W is found to be uniform. That is, when the flow rates of the processing gases adjusted by the flow rate control valves 41a and 41b and the flow rate control valves 42a and 42c are controlled such that the partial pressure ratio of the He gas to the Ar gas is equal to or higher than 50%, a discrepancy between the etching rates at the central portion of the wafer W and the periphery portion thereof is decreased.

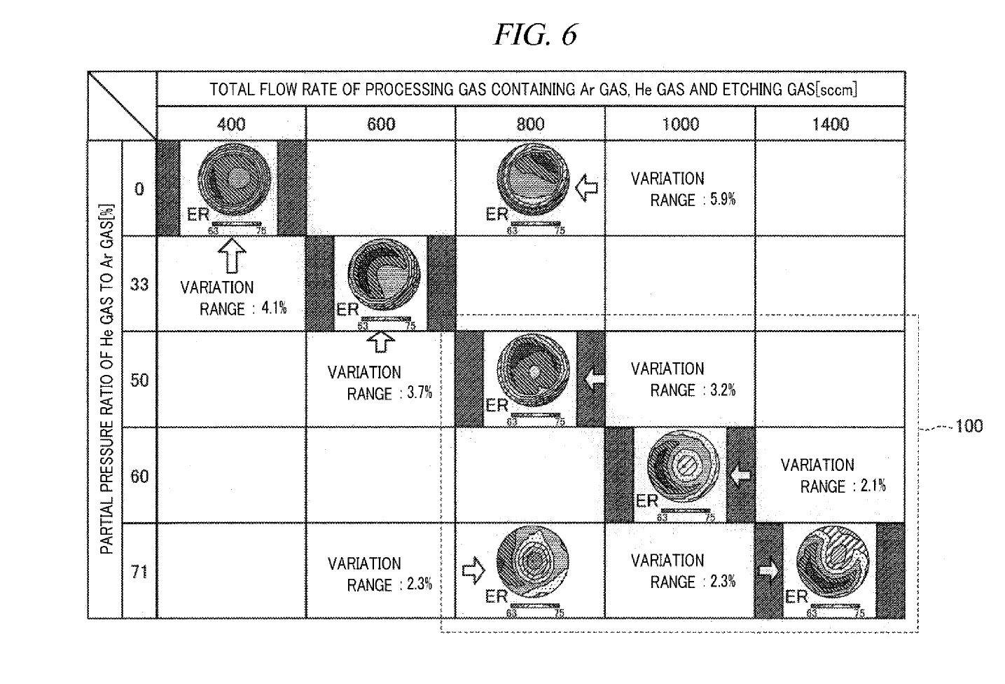

FIG. 6 is a diagram showing simulation results for investigating the effects of the plasma processing method shown in FIG. 5A and FIG. 5B. Simulation results ranging from a left top corner to a right bottom corner of FIG. 6 verify the effect of the plasma processing method shown in FIG. 5A. Simulation results ranging from the central top to the central bottom of FIG. 6 verity the effect of the plasma processing method shown in FIG. 5B. A region 100 surrounded by a dashed line in FIG. 6 depicts simulation results when using the plasma processing method in accordance with the present example embodiment, i.e., when the flow rates of the processing gases adjusted by the flow rate control valves 41a and 41b and the flow rate control valves 42a and 42c are controlled such that the partial pressure ratio of the He gas to the Ar gas is equal to or higher than 50%.

As depicted in the region 100 of FIG. 6, when using the plasma processing method in accordance with the present example embodiment, the variation range of the etching rate ER in the range from the central portion to the periphery portion of the wafer W is found to be reduced, as compared to those in other regions than the region 100.

As discussed above, in the plasma processing apparatus in accordance with the present example embodiment, since the flow rates of the processing gases introduced to the central portion and the periphery portion of the wafer W are controlled such that the partial pressure ratio of the He gas to the Ar gas is equal to or higher than a preset value, the variation range of the etching rate in the range from the central portion to the periphery portion of the wafer W can be reduced. Thus, according to the present example embodiment, uniformity of a processing target surface of the wafer W can be maintained.

Further, a molecular size and a molecular weight of a He gas are smaller than those of an Ar gas. Accordingly, when performing the etching process of removing a Poly-Si film from a wafer W for STI, a damage inflicted on a sidewall of the Poly-Si film by the molecules of the He gas may be reduced as compared to a damage inflicted on a sidewall of the Poly-Si film by the molecules of the Ar gas. In accordance with the present example embodiment, since the flow rates of the processing gases introduced to the central portion and the periphery portion of the wafer W are controlled such that the partial pressure ratio of the He gas to the Ar gas is equal to or higher than the preset value, a damage on the sidewall of the Poly-Si film (fin) can be reduced. As a consequence, in accordance with the present example embodiment, etching of the sidewall of the fin (bowing) can be suppressed.

### EXPLANATION OF REFERENCE NUMERALS

1: Plasma processing apparatus
2: Processing vessel
41a, 41b, 41c, 42a, 42b, 42c: flow rate control valve (flow rate controller)
49: Controller
55: Central inlet unit
61: Peripheral inlet unit
W: Wafer (substrate)

1. A plasma processing apparatus that performs a process on a substrate accommodated in a processing vessel by exciting a processing gas introduced in the processing vessel into plasma, the plasma processing apparatus comprising:
a central inlet unit configured to introduce a processing gas containing at least one of an Ar gas, a He gas and an etching gas toward a central portion of the substrate;
a peripheral inlet unit configured to introduce the processing gas toward a periphery portion of the substrate;
a flow rate adjusting unit configured to adjust a flow rate of the processing gas introduced toward the central portion of the substrate from the central inlet unit, and, also, configured to adjust a flow rate of the processing gas introduced toward the periphery portion of the substrate from the peripheral inlet unit; and
a controller configured to control the flow rates of the processing gas adjusted by the flow rate adjusting unit such that a partial pressure ratio of the He gas to the Ar gas contained in the processing gas is equal to or higher than a preset value.

2. The plasma processing apparatus of claim 1,
wherein the central inlet unit introduces the processing gas containing at least one of the Ar gas and the He gas toward the central portion of the substrate; and
the peripheral inlet unit introduces the processing gas containing the Ar gas and the HBr gas as the etching gas toward the periphery portion of the substrate.

3. The plasma processing apparatus of claim 1,
wherein the controller controls the flow rates of the processing gas adjusted by the flow rate adjusting unit such that the partial pressure ratio of the He gas to the Ar gas is equal to or higher than 0.5.

4. The plasma processing apparatus of claim 1,
wherein the processing gas additionally contains an O₂ gas.

5. A plasma processing method performed in a plasma processing apparatus that performs a process on a substrate accommodated in a processing vessel by exciting a processing gas introduced in the processing vessel into plasma, the plasma processing method comprising:
introducing a processing gas containing at least one of an Ar gas, a He gas and an etching gas toward a central portion of the substrate;
introducing the processing gas toward a periphery portion of the substrate; and
controlling flow rates of the processing gas adjusted by a flow rate adjusting unit configured to adjust a flow rate of the processing gas introduced toward the central portion of the substrate and adjust a flow rate of the processing gas introduced toward the periphery portion of the substrate such that a partial pressure ratio of the He gas to the Ar gas contained in the processing gas is equal to or higher than a preset value.
